(19) United States
(12) Patent Application Publication
(10) Pub. No.: US 2009/0127606 A1
(43) Pub. Date: May 21, 2009

(54) SEMICONDUCTOR INTEGRATED CIRCUIT DEVICE

(75) Inventors: Koichi Kinoshita, Kanagawa-ken (JP); Natsuki Kushiyama, Kanagawa-ken (JP)

Correspondence Address: SPRINKLE IP LAW GROUP, 1301 W. 25TH STREET, SUITE 408, AUSTIN, TX, 78705, US

(73) Assignee: Kabushiki Kaisha Toshiba, Tokyo (JP)

(21) Appl. No.: 12/269,698

(22) Filed: Nov. 12, 2008

(30) Foreign Application Priority Data
Nov. 15, 2007 (JP) 2007-297095

(51) Int. Cl. H01L 29/92

(52) U.S. Cl. 257/296; 257/E29.342

(57) ABSTRACT

A driving circuit and a bus to transmit an output signal from the driving circuit are provided. The driving circuit includes a first P-channel transistor, a second P-channel transistor, an N-channel transistor and a capacitor. The first P-channel transistor includes a drain, a source to connect with a higher potential and a gate to receive a first input signal. The second P-channel transistor includes a drain connected to the bus, a source connected to the drain of the first P-channel transistor and a gate to receive a second input signal. The N-channel transistor includes a drain connected to the drain of the second P-channel transistor, a source to connect with a lower potential and a gate to receive the second input signal. The capacitor includes one end connected to the drain of the first P-channel transistor and another end to connect with the lower potential.

### CROSS REFERENCE TO RELATED APPLICATION

This application is based upon and claims the benefit of priority from the prior Japanese Patent Application No. 2007-297095, filed on Nov. 15, 2007, the entire contents of which are incorporated herein by reference.

### FIELD OF THE INVENTION

The present invention relates to a semiconductor integrated circuit device which is provided with a driving circuit and a bus to transmit a signal outputted from the driving circuit.

### DESCRIPTION OF THE BACKGROUND

With progress in size reduction, high integration, and low-power consumption of a semiconductor integrated circuit, a large number of buses are provided in a semiconductor integrated circuit device to exchange signals among circuits. The semiconductor integrated circuit device is a system LSI or a system on chip (SoC), for example. The buses transmit data signals and clock signals at a high speed. Japanese Patent Application Publication (Kokai) No. 2001-6373 discloses such a semiconductor integrated circuit device.

In the semiconductor integrated circuit device disclosed in the Patent Publication, a signal transmitted through a bus is at a maximum amplitude level of a CMOS circuit. Accordingly, due to a load capacitance between the bus and a ground potential, a large amount of electric power is consumed in the bus. Especially, in the case of a system LSI or an SoC, which is provided with a large number of buses having long wiring to transmit a huge amount of data, a total amount of electric power consumed by the buses is extremely large.

### SUMMARY OF THE INVENTION

An aspect of the invention provides a semiconductor integrated circuit device, which comprises a driving circuit, the driving circuit including a first P-channel insulated gate field effect transistor, a second P-channel insulated gate field effect transistor, a first N-channel insulated gate field effect transistor, and a first capacitor, a bus to transmit an output signal from the driving circuit, and a receiving circuit to receive the output signal transmitted through the bus, wherein the first P-channel insulated gate field effect transistor includes a drain, a source to connect with a higher potential power source, and a gate to receive a first input signal, the second P-channel insulated gate field effect transistor includes a drain connected to the bus, a source connected to the drain of the first P-channel insulated gate field effect transistor, and a gate to receive a second input signal, the first N-channel insulated gate field effect transistor includes a drain connected to the drain of the second P-channel insulated gate field effect transistor, a source to connect with a lower potential power source, and a gate to receive the second input signal, and the first capacitor includes one end connected to the drain of the first P-channel insulated gate field effect transistor, and another end to connect with the lower potential power source.

Another aspect of the invention provides a semiconductor integrated circuit device, which comprises a driving circuit, the driving circuit including a first P-channel insulated gate field effect transistor, a first N-channel insulated gate field effect transistor, a second N-channel insulated gate field effect transistor and a first capacitor, a bus to transmit an output signal from the driving circuit, and a receiving circuit to receive the output signal transmitted through the bus, wherein the first P-channel insulated gate field effect transistor includes a drain connected to the bus, a source to connect with a higher potential power source, and a gate to receive a first input signal, the first N-channel insulated gate field effect transistor includes a source, a drain connected to the drain of the first P-channel insulated gate field effect transistor, and a gate to receive the first input signal, the second N-channel insulated gate field effect transistor includes a drain connected to the source of the first N-channel insulated gate field effect transistor, a source to connect with a lower potential power source, and a gate to receive a second input signal, and the first capacitor includes one end connected to the source of the first N-channel insulated gate field effect transistor, and another end connected to the higher potential power source.

Further another aspect of the invention provides a semiconductor integrated circuit device, which comprises a driving circuit, the driving circuit including a first P-channel insulated gate field effect transistor, a second P-channel insulated gate field effect transistor, a first N-channel insulated gate field effect transistor, a second N-channel insulated gate field effect transistor, a first capacitor, and a second capacitor, a bus to transmit an output signal of the driving circuits, and a receiving circuits to receive the output signal transmitted from the bus, wherein the first P-channel insulated gate field effect transistor includes a drain, a source to connect with a higher potential power source, and a gate to receive a first input signal, the second P-channel insulated gate field effect transistor includes a drain connected to the bus, a source connected to the drain of the first P-channel insulated gate field effect transistor, and a gate to receive a second input signal, the first N-channel insulated gate field effect transistor includes a drain connected to the drain of the second P-channel insulated gate field effect transistor, a source, and a gate to receive the second input signal, the second N-channel insulated gate field effect transistor includes a drain connected to the source of the first N-channel insulated gate field effect transistor, a source to connect with a lower potential power source, and a gate to receive the first input signal, the first capacitor includes one end connected to the drain of the second N-channel insulated gate field effect transistor, and another end connected to the higher potential side power source, and the second capacitor includes one end connected to the drain of the first P-channel insulated gate field effect transistor, and another end to connect with the lower potential side power source.

### BRIEF DESCRIPTION OF THE DRAWINGS

FIG. 1 is a circuit diagram illustrating a semiconductor integrated circuit device according to a first embodiment of the present invention.

FIG. 2 is a view illustrating input/output characteristics of a driving circuit of the first embodiment.

FIG. 3 is a circuit diagram illustrating a semiconductor integrated circuit device according to a second embodiment of the present invention.

FIG. 4 is a view illustrating input/output characteristics of a driving circuit of the second embodiment.

FIG. 5 is a circuit diagram illustrating a semiconductor integrated circuit device according to a third embodiment of the present invention.

FIG. 6 is a view illustrating input/output characteristics of a driving circuit of the third embodiment.

FIG. 7 is a circuit diagram illustrating a semiconductor integrated circuit device according to a fourth embodiment of the present invention.

### DETAILED DESCRIPTION OF THE INVENTION

Hereinafter, embodiments of the present invention will be described with reference to the drawings.

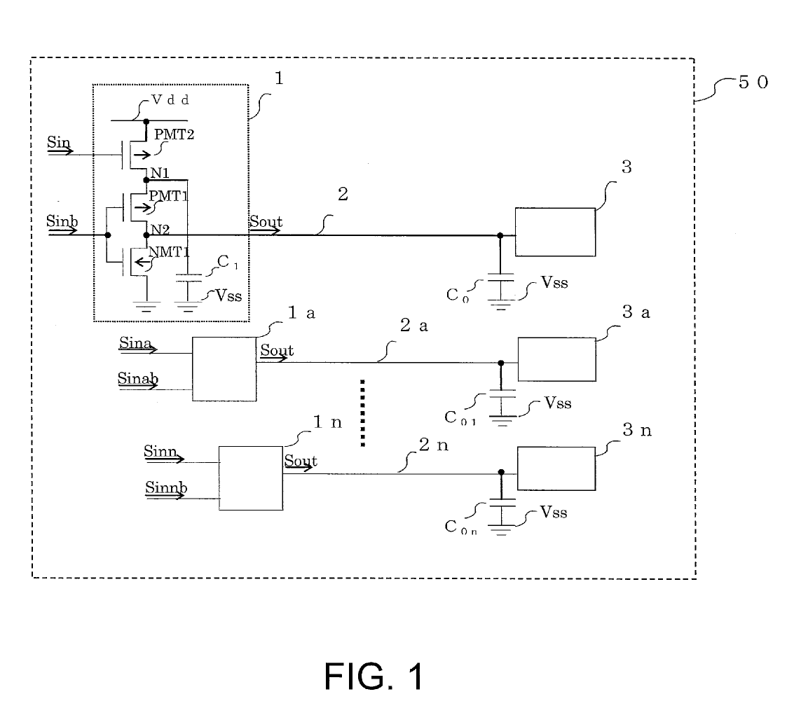

A first embodiment of a semiconductor integrated circuit device according to the present invention will be described with reference to FIG. 1. FIG. 1 is a circuit diagram illustrating the first embodiment.

A semiconductor integrated circuit device 50 illustrated in FIG. 1 is a system LSI. The semiconductor integrated circuit device 50 is provided with an input/output circuit unit, a memory unit, a logic circuit unit, and other units (respectively not shown). Further, the semiconductor integrated circuit device 50 is provided with multiple driving circuits 1, 1a, . . . , 1n, multiple buses 2, 2a, . . . , 2n, and multiple receiving circuit 3, 3a, . . . , 3n.

A data signal or a clock signal generated inside or outside of the semiconductor integrated circuit device 50 is inputted as an input signal to the driving circuits 1, 1a, . . . , 1n. Each of the driving circuits 1, 1a, . . . , 1n outputs a signal obtained by reducing level of the input signal to each of the buses 2, 2a, . . . , 2n. A signal (either a data signal or a clock signal) transmitted from the buses 2, 2a, . . . , 2n is inputted to the receiving circuit 3, 3a, . . . , 3n. The receiving circuit 3, 3a, . . . , 3n may store the input signal. Further, the receiving circuit 3, 3a, . . . , 3n may perform a signal processing. The receiving circuit 3, 3a, . . . , 3n may perform a signal processing on the basis of the input signal.

The driving circuit 1 is provided with a P-channel MOS transistor PMT1, a P-channel MOS transistor PMT2, and an N-channel MOS transistor NMT1, respectively as insulated gate field effect transistors, and a capacitor C1.

A source of the P-channel MOS transistor PMT2 is connected to a higher potential power source Vdd. A drain of the P-channel MOS transistor PMT2 is connected to a node N1. An input signal Sin is inputted to a gate of the P-channel MOS transistor PMT2. A source of the P-channel MOS transistor PMT1 is connected to the node N1. A drain of the P-channel MOS transistor PMT1 is connected to a node N2. An input signal Sinb having an opposite phase to that of the input signal Sin is inputted to a gate of the P-channel MOS transistor PMT1.

A drain of the N-channel MOS transistor NMT1 is connected to the node N2. A source of the N-channel MOS transistor NMT1 is connected to a lower potential power source (ground potential) Vss. The input signal Sinb is inputted to a gate of the N-channel MOS transistor NMT1. One end of the capacitor C₁ is connected to the node N1, which is the drain of the P-channel MOS transistor PMT2 and the source of the P-channel MOS transistor PMT1. The other end of the capacitor C₁ is connected to the lower potential power source (ground potential) Vss.

The P-channel MOS transistor PMT1 and the N-channel MOS transistor NMT1 constitute an inverter. From the node N2, which is the drain of the P-channel MOS transistor PMT1 and the drain of the N-channel MOS transistor NMT1, an output signal Sout with the same phase as that of the input signal Sin is outputted.

The bus 2 is provided between the driving circuit 1 and the receiving circuit 3. The bus 2 transmits the output signal Sout outputted from the driving circuit 1 to the receiving circuit 3. A bus capacitance C₀ is formed as s load capacitance between the bus 2 and the lower potential power source (ground potential) Vss. The output signal Sout of the driving circuit 1, which is transmitted through the bus 2, is inputted to the receiving circuit 3.

The driving circuit la has a similar circuit configuration as that of the driving circuit 1. An input signal Sina and an input signal Sinab with a phase opposite to that of the input signal Sina are inputted to the driving circuit 1a. The driving circuit la outputs an output signal Souta having the same phase as that of the input signal Sina. The bus 2a is provided between the driving circuit 1a and the receiving circuit 3a. The bus 2a transmits the output signal Souta outputted from the driving circuit la to the receiving circuit 3a. A bus capacitance C₀₁ is formed as a load capacitance between the bus 2a and the lower potential power source (ground potential) Vss. The output signal Souta of the driving circuit 1a, which is transmitted from the bus 2a, is inputted to the receiving circuit 3a.

The driving circuit 1n has a similar circuit configuration as that of the driving circuit 1. An input signal Sinn and an input signal Sinnb having an phase opposite to that of the input signal Sinn are inputted to the driving circuit 1n. The driving circuit 1n outputs an output signal Soutn having the same phase as that of the input signal Sinn. The bus 2n is provided between the driving circuit 1n and the receiving circuit 3n. The bus 2n transmits the output signal Soutn outputted from the driving circuit 1n to the receiving circuit 3n. A bus capacitance C₀ₙ is formed as a load capacitance between the bus 2n and the lower potential power source (ground potential) Vss. The output signal Soutn of the driving circuit 1n, which is transmitted from the bus 2n, is inputted to the receiving circuit 3n.

It is desirable that the capacitor C₁ has the same configuration as that of the bus capacitance C₀. If the bus 2 is a wiring, for example, the capacitor C₁ is desirably formed in a dummy wiring shape so that the wiring is partially guarded. Further, if the bus 2 is a gate, for example, the capacitance C₁ is desirably formed in a similar pattern shape obtained by reducing size of the gate. Forming the bus 2 in such a shape stabilizes the amplitude of the output signal Sout outputted from the driving circuit 1 against process variation.

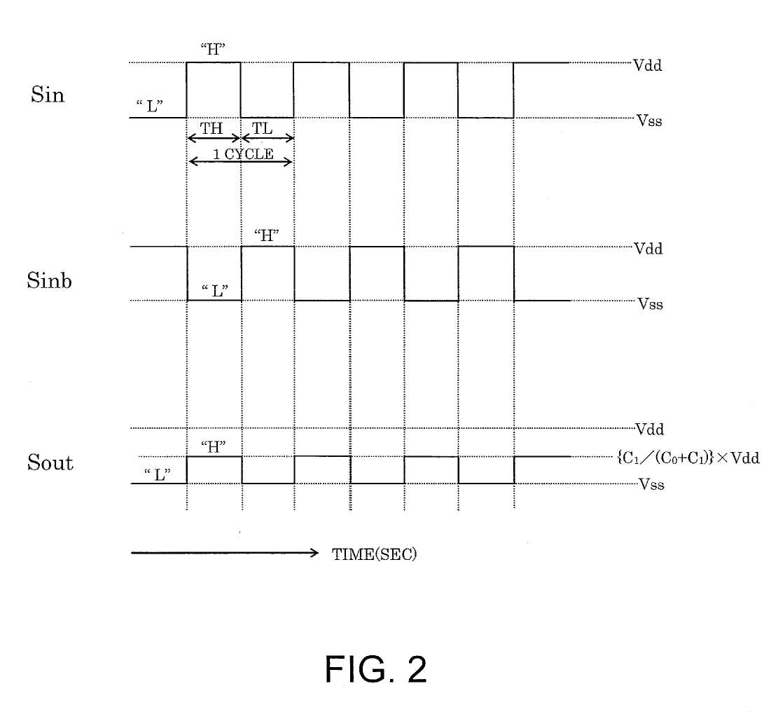

Characteristics of the driving circuit 1 illustrated in FIG. 1 will be described with reference to FIG. 2. FIG. 2 is a view illustrating input/output characteristics of the driving circuit 1.

As shown in FIG. 2, a high level of the input signal Sin, which is inputted to the driving circuit 1, is Vdd. A low level of the input signal Sin is Vss. A high level period in one cycle of the input signal Sin is TH. A low level period in one cycle of the input signal Sin is TL.

A high level of the input signal Sinb, which has a phase opposite to that of the input signal Sin inputted to the driving circuit 1, is Vdd. A low level of the input signal Sinb is Vss. A high level period of one cycle of the input signal Sinb is TH. A low level period of one cycle of the input signal Sinb is TL. In FIG. 2, in the input signals Sin and Sinb, duty is set to TH:TL=50%:50%.

The output signal Sout outputted from the driving circuit 1 is a signal having the same phase as that of the input signal Sin. Due to the existence of the capacitance of the capacitor C₁ and the bus capacitance (load capacitance) C₀ of the bus 2, the signal level of the output signal Sout is on the side of the lower potential power source (ground potential) Vss. The amplitude of the output signal Sout is reduced. The high level Sout (H) of the output signal Sout and the low level Sout (L) of the output signal Sout are expressed by the following formulas:

Sout(H)={C₁/(C₀+C₁)}×Vdd (1)

Sout(L)=Vss (2)

In general, electric power P consumed by a CMOS circuit is expressed by the following formula. In the formula, a switching probability is represented by Pt. A clock frequency is represented by f. A load capacitance is represented by CL Signal amplitude is represented by Vs. A power source voltage is represented by Vdd:

P=Pt×f×C_{L}×V_{S}×Vdd (3)

Electric power Pb consumed by the bus 2 is expressed from the formulas (1) to (3) as follows. In the following formula, a load capacitance of the bus 2 is represented by C₀, and a capacitance of the capacitor C₁ is represented by C₁.

Pb=Pt×f×C₀×{C₁/(C₀+C₁)}²×Vdd² (4)

When the switching probability Pt is 1, the electric power Pb consumed by the bus 2 is expressed by the following formula:

Pb=f×C₀×{C₁/(C₀+C₁)}²×Vdd² (5)

Compared with the case where any capacitor C₁ is not provided in the driving circuit 1, providing the capacitor C₁ in the driving circuit 1 makes the amount of electric power consumed by the bus 2 to be reduced by {C₁/(C₀+C₁)}². Similarly, each of the driving circuit 1a, . . . , 1n other than the driving circuit 1 is also provided with a capacitor. Accordingly, the amount of electric power consumed by the buses 2, 2a, . . . , 2n can also be reduced.

Electric power consumption in the semiconductor integrated circuit device 50 can be reduced.

In the present embodiment, the amplitudes of all of the signals transmitted through the buses 2, 2a, . . . , 2n are reduced by the driving circuits 1, 1a, . . . , 1n. Amplitude of a signal, which is transmitted through a selected bus, may be reduced.

A second embodiment of the semiconductor integrated circuit device according to the invention will be described with reference to a drawing.

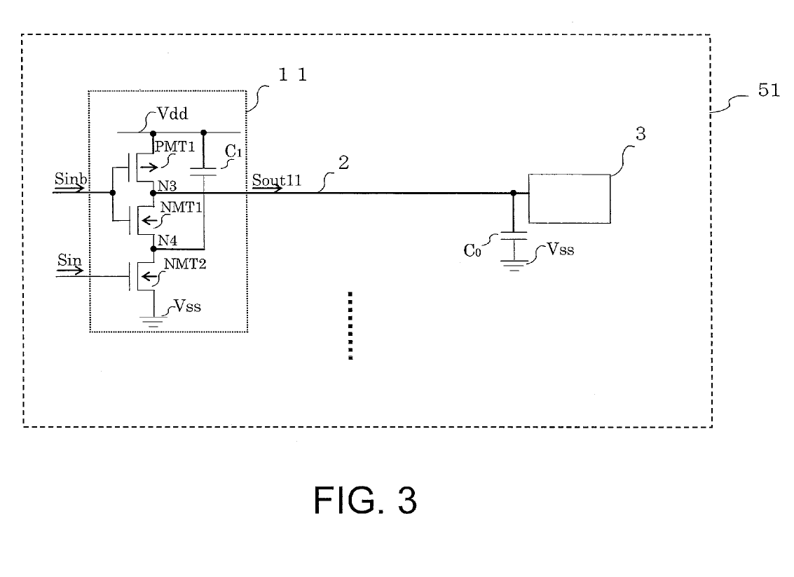

FIG. 3 is a circuit diagram illustrating a semiconductor integrated circuit device according to the second embodiment.

In FIG. 3, the same portions as those in FIG. 1 are denoted by the same reference numerals.

As shown in FIG. 3, a semiconductor integrated circuit device 51 is a system LSI. The semiconductor integrated circuit device 51 is provided with a driving circuit 11, a bus 2, and a receiving circuit 3. The semiconductor integrated circuit device 51 is provided with multiple other driving circuits, multiple other buses, multiple receiving circuits (respectively not shown), which are respectively similar to the driving circuit 11 the bus 2, and the receiving circuit 3 in the first embodiment. The semiconductor integrated circuit device 51 is provided with an input/output circuit unit, a memory unit, a logic circuit unit, and other units (respectively not shown), which are respectively similar to those of the first embodiment.

The driving circuit 11 illustrated in FIG. 3 is provided with a P-channel MOS transistor PMT1, an N-channel MOS transistor NMT1, an N-channel MOS transistor NMT2, and a capacitor C₁.

A source of the P-channel MOS transistor PMT1 is connected to a higher potential power source Vdd. A drain of the P-channel MOS transistor PMT1 is connected to a node N3. An input signal Sinb is inputted to a gate of the P-channel MOS transistor PMT1. A drain of the N-channel MOS transistor NMT1 is connected to the node N3. A source of the N-channel MOS transistor NMT1 is connected to a node N4. The input signal Sinb is inputted to a gate of the N-channel MOS transistor NMT1. A drain of the N-channel MOS transistor NMT2 is connected to the node N4. A source of the N-channel MOS transistor NMT2 is connected to a lower potential power source (ground potential) Vss. An input signal Sin having an opposite phase to that of the input signal Sinb is inputted to a gate of the N-channel MOS transistor NMT2. One end of the capacitor C₁ is connected to a higher potential power source Vdd. The other end of the capacitor C₁ is connected to the node N4, which is, the source of the N-channel MOS transistor NMT1 and the drain of the N-channel MOS transistor NMT2.

The P-channel MOS transistor PMT1 and the N-channel MOS transistor NMT1 constitute an inverter. From the node N3, which is the drain of the P-channel MOS transistor PMT1 and the drain of the N-channel MOS transistor NMT1, an output signal Sout11 having the same phase as that of the input signal Sin is outputted.

The bus 2 is provided between the driving circuit 11 and the receiving circuit 3. The output signal Sout11 outputted from the driving circuit 11 is transmitted to the receiving circuit 3. A bus capacitance C₀ is formed as a load capacitance between the bus 2 and the lower potential power source (ground potential) Vss. The output signal Sout11 of the driving circuit 11 transmitted through the bus 2 is inputted to the receiving circuit 3.

The capacitor C₁ has the same configuration as that of the bus capacitance C₀. If the bus 2 is a wiring, for example, the capacitor C₁ is desirably formed in a dummy wiring shape so that the wiring is partially guarded. Furthermore, if the bus 2 is a gate, the capacitor C₁ is desirably formed in a similar pattern shape obtained by reducing size of the gate. Forming the bus 2 in such a shape stabilizes the amplitude of the output signal Sout outputted from the driving circuit 11 against process variation.

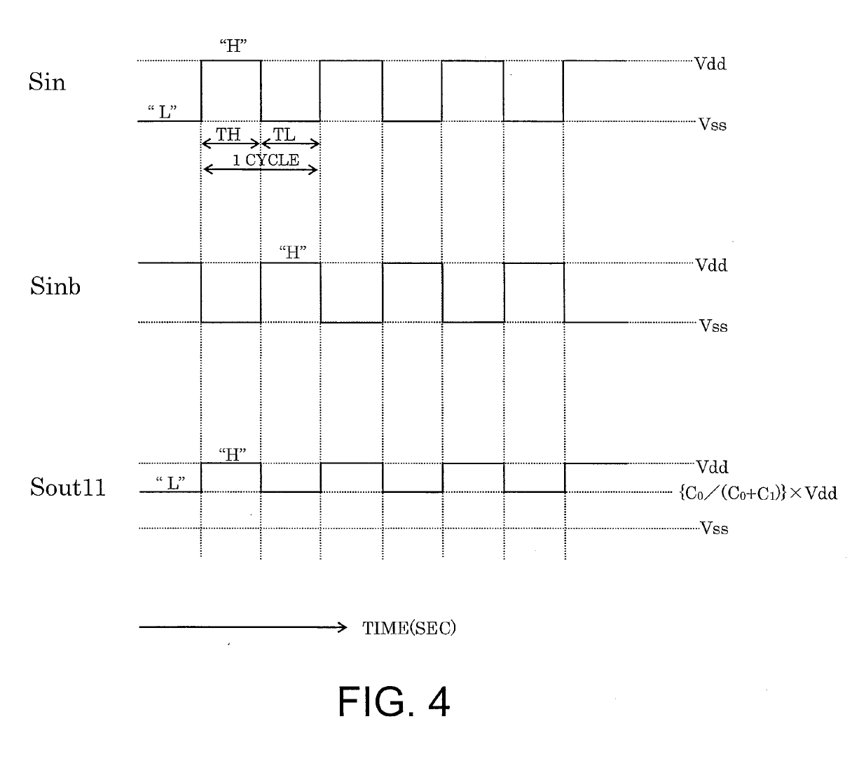

A performance of the driving circuit 11 will be described with reference to FIG. 4. FIG. 4 is a view illustrating input/output characteristics of the driving circuit 11.

As illustrated in FIG. 4, the input signal Sin and the input signal Sinb are inputted to the driving circuit 11. The output signal Sout11 is outputted from the driving circuit 11. The output signal Sout11 is a signal having the same phase as that of the input signal Sin. Due to the existence of the capacitance of the capacitor C₁ and the bus capacitance (load capacitance) C₀ of the bus 2, the amplitude of the output signal Sout11 is reduced. A high level Sout11(H) of the output signal Sout11 and a low level Sout11(L) of the output signal Sout are expressed as follows:

Sₒᵤₜ11(H)=Vdd (6)

Sₒᵤₜ11(L)={C₀/(C₀+C₁)}×Vdd (7)

Electric power Pb consumed by the bus 2 is expressed by the following formula in accordance with the formula (3) in the first embodiment and the above formulas (6) and (7). In the formula (8), the load capacitance of the bus 2 is represented by C₀ The capacitance of the capacitor C₁ is represented by C₁. A switching probability Pt is 1 (one).

Pb=f×C₀×{C₁/(C₀+C₁)}×Vdd² (8)

Compared with the case where any capacitor C₁ is not provided in the driving circuit 1, providing the capacitor C₁ in the driving circuit 11 may make the amount of electric power being consumed by the bus 2 to be reduced by {C₁/(C₀+C₁)}. Similarly, each of the driving circuits (not shown) other than the driving circuit 11 is also provided with a capacitor. Accordingly, the amount of electric power consumed by the buses respectively connected to the driving circuits can be largely reduced.

The output signal Sout of the first embodiment is located on the side of the lower potential power source (ground potential) Vss, whereas the output signal Sout11 of the present embodiment is located on the side of the higher potential power source Vdd. It is desirable to set the level of the output signal Sout11 in view of the capacitance of a well region where the driving circuit 11, the bus 2 and the receiving circuit 3 is formed, the level of noise being generated in the driving circuit 11, the bus 2, the receiving circuit 3 and other circuits, a transistor configuration on the side of the receiving circuit 3.

Due to the existence of the capacitance of the capacitor C₁ and the bus capacitance C₀, the signal level of the output signal Sout11 is on the side of the higher potential power source Vdd. The amplitude of the output signal Sout11 is reduced. Similarly, as for the buses other than the bus 2, due to the existence of the capacitance of capacitor of the driving circuits and the bus capacitance, the levels of the output signals outputted from the respective driving circuits are on the side of the higher potential power source Vdd. The amplitude of the output signals is reduced.

The amount of electric power being consumed by the bus can be largely reduced. Therefore, electric power consumption in the semiconductor integrated circuit device 51 can be reduced.

In the above embodiment, only the amplitude of a signal transmitted through a selected bus may be reduced among the amplitudes of the respective signals, which are transmitted through the buses provided in the semiconductor integrated circuit device 51.

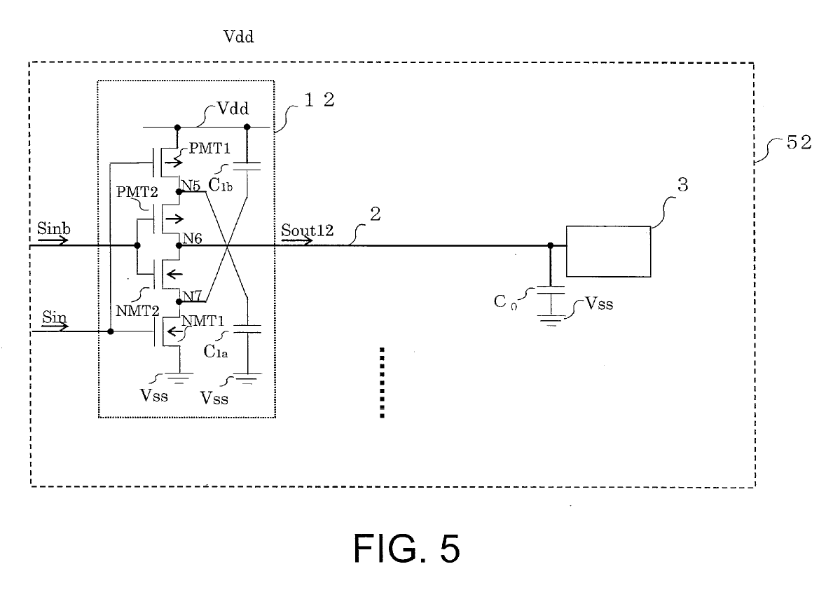

A semiconductor integrated circuit device according to a third embodiment of the present invention will be described with reference to a drawing. FIG. 5 is a circuit diagram illustrating a semiconductor integrated circuit device according to the third embodiment.

In FIG. 5, the same portions as those in FIG. 1 and FIG. 3 are denoted by the same reference numerals.

As shown in FIG. 5, a semiconductor integrated circuit device 52 is provided with a driving circuit 12, a bus 2, and a receiving circuit 3. The semiconductor integrated circuit device 52 is a system LSI. The semiconductor integrated circuit device 52 is, similarly to the first and second embodiments, provided with multiple other driving circuits, multiple other buses, and multiple other receiving circuits (respectively not shown). Further, the semiconductor integrated circuit device 52 is provided with an input/output circuit unit, a memory unit, a logic circuit unit, and other units (respectively not shown).

The driving circuit 12 is provided with a P-channel MOS transistor PMT1, a P-channel MOS transistor PMT2, an N-channel MOS transistor NMT1, an N-channel MOS transistor NMT2, a capacitor C₁ₐ, and a capacitor C_{1b}.

A source of the P-channel MOS transistor PMT1 is connected to a higher potential power source Vdd. A drain of the P-channel MOS transistor PMT1 is connected to a node N5. An input signal Sin is inputted to a gate of the P-channel MOS transistor PMT1.

A source of the P-channel MOS transistor PMT2 is connected to the node N5. A drain of the P-channel MOS transistor PMT2 is connected to a node N6. An input signal Sinb having a phase opposite to that of the input signal Sin is inputted to a gate of the P-channel MOS transistor PMT2.

A drain of the N-channel MOS transistor NMT2 is connected to the node N6. A source of the N-channel MOS transistor NMT2 is connected to a node N7. The input signal Sinb is inputted to a gate of the N-channel MOS transistor NMT2. A drain of the N-channel MOS transistor NMT1 is connected to the node N7. A source of the N-channel MOS transistor NMT1 is connected to a lower potential power source (ground potential) Vss. The input signal Sin is inputted to a gate of the N-channel MOS transistor NMT1.

The P-channel MOS transistor PMT1 and the N-channel MOS transistor NMT1 constitute an inverter. The P-channel MOS transistor PMT2 and the N-channel MOS transistor NMT2 constitute an inverter.

One end of the capacitor C₁ₐ is connected to the node N5, which is the drain of the P-channel MOS transistor PMT1 and the source of the P-channel MOS transistor PMT2. The other end of the capacitor C₁ₐ is connected to the lower potential power source (ground potential) Vss. One end of the capacitor C_{1b} is connected to the higher potential power source Vdd. The other end of the capacitor C_{1b} is connected to the node N7, which is the source of the N-channel MOS transistor NMT2 and the drain of the N-channel MOS transistor NMT1.

An output signal Sout12 having the same phase as that of the input signal Sin is outputted from the node N6, which is the drain of the P-channel MOS transistor PMT2 and the drain of the N-channel MOS transistor NMT2.

The bus 2 is provided between the driving circuit 12 and the receiving circuit 3. The output signal Sout12 outputted from the driving circuit 12 is transmitted to the receiving circuit 3. A bus capacitance C₀ is formed as a load capacitance between the bus 2 and the lower potential power source (ground potential) Vss. The output signal Sout12 of the driving circuit 12 transmitted from the bus 2 is inputted to the receiving circuit 3.

The capacitors C₁ₐ and C_{1b} have the same configuration as that of the bus capacitance C₀. If the bus 2 is a wiring, for example, the capacitors C₁ₐ and C_{1b} are preferably formed in a dummy wiring shape so that the wiring is partially guarded. If the bus 2 is a gate, the capacitor C₁ₐ and C_{1b} are preferably formed in a similar pattern shape obtained by reducing size of the gate. Forming the bus 2 in such a shape stabilizes the amplitude of the output signal Sout12 outputted from the driving circuit 12 against process variation.

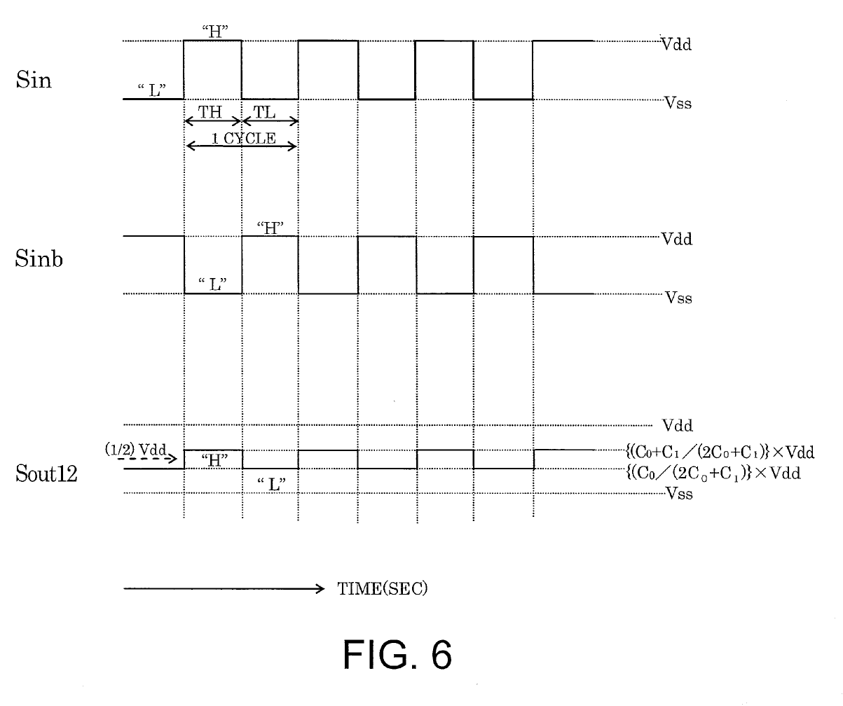

A performance of the driving circuit 12 will be described with reference to FIG. 6. FIG. 6 is a view illustrating input/output characteristics of the driving circuit 12.

As illustrated in FIG. 6, the input signal Sin and the input signal Sinb are inputted to the driving circuit 12. The output signal Sout12 is outputted from the driving circuit 12. The output signal Sout12 is a signal having the same phase as that of the input signal Sin. The amplitude of the output signal Sout12 is reduced due to the existence of the capacitance of the capacitor C₁ₐ, the capacitance of the capacitor C_{1b}, and the bus capacitance (a load capacitance) C₀ of the bus 2. Accordingly, when the capacitance of the capacitor C₁ₐ and the capacitor C_{1b} are represented by C₁, a high level Sout12(H) of the output signal Sout12 and a low level Sout12(L) of the output signal Sout12 are expressed as follows:

Sout12(H){(C₀+C₁)/(2×C₀+C₁)}×Vdd (9)

Sout12(L){C₀/(2×C₀+C₁)}×Vdd (10)

Electric power Pb being consumed by the bus 2 is expressed as follows in accordance with the formula (3) in the first embodiment and the above formulas (9), (10), when the load capacitance of the bus 2 is represented by C₀, and the switching probability Pt is 1 (one).

Pb=f×C₀×[{(C₀30 C₁)×C₁}/(2×C₀+C₁)²]×Vdd² (11)

Compared with the case where any capacitor C₁ₐ and capacitor C_{1b} are not provided in the driving circuit 12, providing the capacitor C₁ₐ and the capacitor C_{1b} in the driving circuit 12 may make the amount of electric power being consumed by the bus 2 to be reduced by [{(C₀+C₁)×C₁}/(2×C₀+C₁)²]. Similarly, each of the driving circuits other than the driving circuit 12 is also provided with a capacitor. Accordingly, the amount of electric power consumed by the buses provided in the semiconductor integrated circuit device 52 can be largely reduced.

While the output signal Sout of the first embodiment is on the side of the lower potential power source (ground potential) Vss, the output signal Sout12 of the present embodiment exists near the (1/2) Vdd.

It is desirable to set the level of the output signal Sout12 in view of the capacitance of well regions where the driving circuit 12, the bus 2, and the receiving circuit 3 are formed, the level of noise generated in the driving circuit 12, the bus 2, the receiving circuit 3 and other circuits, and a transistor configuration in the side of the receiving circuit 3.

Due to the existence of the capacitance of the capacitor C₁ₐ, the capacitance of the capacitor C_{1b}, and the bus capacitance C₀, the signal level of the output signal Sout12 is in the vicinity of (1/2) Vdd. The amplitude of the output signal Sout12 is reduced. Similarly, as for the buses other than the bus 2, the levels of output signals respectively outputted from the driving circuits are in the vicinity of (1/2) Vdd, due to the capacities of respective capacitors located on the side of the lower potential power source (ground potential) Vss of the driving circuits, the capacities of respective capacitors located on the side of the higher potential power source Vdd of the driving circuits and the bus capacitance. Thus, the amplitudes of the respective output signals are reduced.

The amount of electric power being consumed by the bus can be largely reduced. Therefore, electric power consumption in the semiconductor integrated circuit device 52 can be reduced.

In the present embodiment, only the amplitude of a signal being transmitted through a selected bus may be reduced.

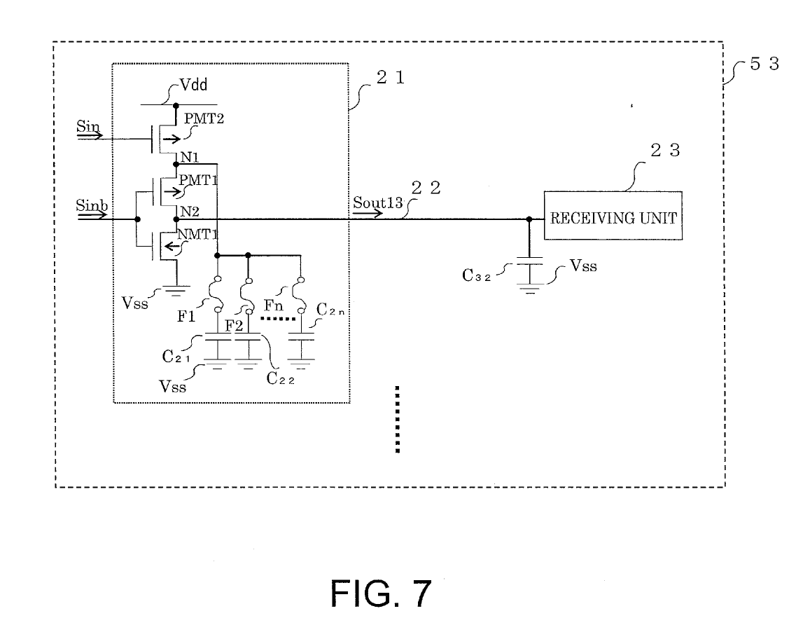

A semiconductor integrated circuit device according to a fourth embodiment of the present invention will be described with reference to a drawing. FIG. 7 is a circuit diagram illustrating a semiconductor integrated circuit device according to a fourth embodiment.

A semiconductor integrated circuit device 53 illustrated in FIG. 7 is a system LSI. The semiconductor integrated circuit device 53 is provided with an input/output circuit unit, a memory unit, a logic circuit unit, and other units (respectively not shown). Further, the semiconductor integrated circuit device 53 is provided with a driving circuit 21, a bus 22, and a receiving unit 23. The semiconductor integrated circuit device 53 is, similarly to the first embodiment, provided with multiple other driving circuits, multiple other buses, and multiple other receiving units (respectively not shown).

The driving circuit 21 is provided with a P-channel MOS transistor PMT1, PMT2, an N-channel MOS transistor NMT1, a fuse F1, F2, . . . , Fn, a capacitor C₂₁, C₂₂, . . . , C₂ₙ.

A source of the P-channel MOS transistor PMT2 is connected to a higher potential power source Vdd. A drain of the P-channel MOS transistor PMT2 is connected to a node N1. An input signal Sin is inputted to a gate of the P-channel MOS transistor PMT2. A source of the P-channel MOS transistor PMT1 is connected to the node N1. A drain of the P-channel MOS transistor PMT1 is connected to a node N2. An input signal Sinb having a phase opposite to that of the input signal Sin is inputted to a gate of the P-channel MOS transistor PMT1.

A drain of the N-channel MOS transistor NMT1 is connected to the node N2. A source of the N-channel MOS transistor NMT1 is connected to a lower potential power source (ground potential) Vss. The input signal Sinb is inputted to a gate of the N-channel MOS transistor NMT1.

An n number of series circuits, which are constituted by respective cascade arrangement of the fuses F1, . . . , Fn and the capacitors C₂₁, . . . , C₂ₙ are connected between the node N1 and the lower potential power source (ground potential) Vss. The series circuits are connected in parallel with each other.

One end of the fuse F1 is connected to the node N1. One end of the capacitor C₂₁ is connected to the other end of the fuse F1. The other end of the capacitor C₂₁ is connected to the lower potential power source (ground potential) Vss. One end of the fuse F2 is connected to the node N1. One end of the capacitor C₂₂ is connected to the other end of the fuse F2. The other end of the capacitor C₂₂ is connected to the lower potential power source (ground potential) Vss. One end of the fuse Fn is connected to the node N1. One end of the capacitor C₂ₙ is connected to the other end of the fuse Fn. The other end of the capacitor C₂ₙ is connected to the lower potential power source (ground potential) Vss.

The capacitors C₂₁, . . . , C₂ₙ are provided on the side of the lower potential power source (ground potential) Vss, but the fuses F1, . . . , Fn may be provided on the side of the lower potential power source (ground potential) Vss.

An output signal Sout 13 having the same phase as that of the input signal Sin is outputted from the node N2, which is the drain of the P-channel MOS transistor PMT1 and the drain of the N-channel MOS transistor NMT1.

The bus 22 is a global bus or a main bus for transmitting large-scale information containing a large number of bits. The bus 22 is provided between the driving circuit 21 and the receiving unit 23. The bus 22 transmits the output signal Sout 13 outputted from the driving circuit 21 to the receiving unit 23.

A bus capacitance C₃₂ is formed as a load capacitance between the bus 22 and the lower potential power source (ground potential) Vss. The output signal Sout 13 of the driving circuit 21 transmitted from the bus 22 is inputted to the receiving unit 23. The receiving unit 23 performs processing such as storing or transferring large-scale information containing a large number of bits.

The fuses F1, . . . , Fn are cut with an electric cutting means or a laser, after a chip of the semiconductor integrated circuit device 53 is manufactured, selectively according to requirement of characteristic level of the chip.

A capacitor connected to a cut fuse is no longer connected to the node N1. Only a capacitor connected to an uncut fuse functions as a capacitor connected between the node N1 and the lower potential power source (ground potential) Vss.

Due to the existence of the capacitance of a capacitor connected to the node N1 and the bus capacitance (load capacitance) C₃₂ of the bus 22, the amplitude of the output signal Sout 13 can be reduced. As a result, it is possible to reduce the amount of electric power consumed by the bus 22 in accordance with the characteristic level of the chip of the semiconductor integrated circuit device 53. As for the other buses, similarly, electric power consumption can be reduced.

In the present embodiment, the level of the output signal Sout 13 is positioned on the side of the lower potential power source (ground potential) Vss, due to the capacitance of a capacitor connected to an uncut fuse and the bus capacitance (load capacitance) C₃₂ of the bus 22. Thus, the amplitude of the output signal Sout 13 is reduced.

The amount of electric power consumed by the bus 22 can be largely reduced. Therefore, electric power consumption can be reduced in accordance with the characteristic level of the chip of the semiconductor integrated circuit device 53.

Each of the above-described embodiments is a system LSI. The invention can also be applied to a system on chip (SoC) including an input/output circuit unit, a memory unit, a logic circuit unit, an analogue circuit unit, and other units, and to a general LSI.

Further, in the fourth embodiment described above, series circuits including a fuse and a capacitor are connected to the side of the lower potential power source (ground potential) so as to be connected in parallel with each other. The series circuits including a fuse and a capacitor may be connected to the higher potential power source side so as to be connected in parallel with each other. Series circuits, each of which is constituted by a fuse and a capacitor, may be connected respectively to the side of the lower potential power source (ground potential) and to the side of the higher potential power source so as to be connected in parallel with each other.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor integrated circuit device, comprising:
a driving circuit, the driving circuit including a first P-channel insulated gate field effect transistor, a second P-channel insulated gate field effect transistor, a first N-channel insulated gate field effect transistor, and a first capacitor;
a bus to transmit an output signal from the driving circuit; and
a receiving circuit to receive the output signal transmitted through the bus, wherein
the first P-channel insulated gate field effect transistor includes a drain, a source to connect with a higher potential power source, and a gate to receive a first input signal,
the second P-channel insulated gate field effect transistor includes a drain connected to the bus, a source connected to the drain of the first P-channel insulated gate field effect transistor, and a gate to receive a second input signal,
the first N-channel insulated gate field effect transistor includes a drain connected to the drain of the second P-channel insulated gate field effect transistor, a source to connect with a lower potential power source, and a gate to receive the second input signal, and
the first capacitor includes one end connected to the drain of the first P-channel insulated gate field effect transistor, and another end to connect with the lower potential power source.

2. The semiconductor integrated circuit device according to claim 1, wherein the first and second input signals have phases opposite to each other.

3. The semiconductor integrated circuit device according to claim 1, wherein amplitude of a signal outputted from the drain of the second P-channel insulated gate field effect transistor to the bus is smaller than the amplitude of the first input signal.

4. The semiconductor integrated circuit device according to claim 1, wherein the first capacitor is constituted by a plurality of second capacitors connected in parallel with each other.

5. The semiconductor integrated circuit device according to claim 4, further comprising fuses, wherein
the fuses are respectively connected in series to the second capacitors to constitute series circuits, the series circuits being connected in parallel with each other.

6. A semiconductor integrated circuit device, comprising:
a driving circuit, the driving circuit including a first P-channel insulated gate field effect transistor, a first N-channel insulated gate field effect transistor, a second N-channel insulated gate field effect transistor and a first capacitor;
a bus to transmit an output signal from the driving circuit; and
a receiving circuit to receive the output signal transmitted through the bus, wherein
the first P-channel insulated gate field effect transistor includes a drain connected to the bus, a source to connect with a higher potential power source, and a gate to receive a first input signal,
the first N-channel insulated gate field effect transistor includes a source, a drain connected to the drain of the first P-channel insulated gate field effect transistor, and a gate to receive the first input signal,
the second N-channel insulated gate field effect transistor includes a drain connected to the source of the first N-channel insulated gate field effect transistor, a source to connect with a lower potential power source, and a gate to receive a second input signal, and
the first capacitor includes one end connected to the source of the first N-channel insulated gate field effect transistor, and another end connected to the higher potential power source.

7. The semiconductor integrated circuit device according to claim 6, wherein the first and second input signals have phases opposite to each other.

8. The semiconductor integrated circuit device according to claim 6, wherein amplitude of a signal outputted from the drain of the first P-channel insulated gate field effect transistor to the bus is smaller than the amplitude of the second input signal.

9. The semiconductor integrated circuit device according to claim 6, wherein the first capacitor is constituted by a plurality of second capacitors connected in parallel with each other.

10. The semiconductor integrated circuit device according to claim 9, further comprising fuses, wherein
the fuses are respectively connected in series to the second capacitors to constitute series circuits, the series circuits being connected in parallel with each other.

11. A semiconductor integrated circuit device, comprising:
a driving circuit, the driving circuit including a first P-channel insulated gate field effect transistor, a second P-channel insulated gate field effect transistor, a first N-channel insulated gate field effect transistor, a second N-channel insulated gate field effect transistor, a first capacitor, and a second capacitor;
a bus to transmit an output signal of the driving circuits; and
a receiving circuits to receive the output signal transmitted from the bus, wherein
the first P-channel insulated gate field effect transistor includes a drain, a source to connect with a higher potential power source, and a gate to receive a first input signal,
the second P-channel insulated gate field effect transistor includes a drain connected to the bus, a source connected to the drain of the first P-channel insulated gate field effect transistor, and a gate to receive a second input signal,
the first N-channel insulated gate field effect transistor includes a drain connected to the drain of the second P-channel insulated gate field effect transistor, a source, and a gate to receive the second input signal,
the second N-channel insulated gate field effect transistor includes a drain connected to the source of the first N-channel insulated gate field effect transistor, a source to connect with a lower potential power source, and a gate to receive the first input signal,
the first capacitor includes one end connected to the drain of the second N-channel insulated gate field effect transistor, and another end connected to the higher potential side power source, and
the second capacitor includes one end connected to the drain of the first P-channel insulated gate field effect transistor, and another end to connect with the lower potential side power source.

12. The semiconductor integrated circuit device according to claim 11, wherein the first and second input signals have phases opposite to each other.

13. The semiconductor integrated circuit device according to claim 11, wherein amplitude of a signal outputted from the drain of the second P-channel insulated gate field effect transistor to the bus is smaller than the amplitude of the first input signal.

14. The semiconductor integrated circuit device according to claim 11, wherein
the first capacitor is constituted by a plurality of third capacitors connected in parallel with each other, and
the second capacitor is constituted by a plurality of fourth capacitors connected in parallel with each other.

15. The semiconductor integrated circuit device according to claim 14, further comprising first fuses and second fuses, wherein
the first fuses are respectively connected in series to the third capacitors to constitute first series circuits, the first series circuits being connected in parallel with each other,
the second fuses are respectively connected in series to the fourth capacitors to constitute second series circuits, the second series circuits being connected in parallel with each other.
